(19) United States
(12) Patent Application Publication
(10) Pub. No.: US 2007/0064957 A1
(43) Pub. Date: Mar. 22, 2007

(54) System for reproducing sound

(76) Inventor: Jean-Daniel Pages, Sucy en Brie (FR)

Correspondence Address: SOFER & HAROUN LLP., 317 MADISON AVENUE, SUITE 910, NEW YORK, NY, 10017, US

(21) Appl. No.: 11/414,731

(22) Filed: Apr. 28, 2006

(30) Foreign Application Priority Data
Sep. 20, 2005 (FR) 05-52824

(51) Int. Cl. H03G 3/00; H04R 5/00

(52) U.S. Cl. 381/61; 381/23

(57) ABSTRACT

Devices and method for reproducing sound and transmitting a first sound signal and a second sound signal includes a producer having a means for coding the second sound signal, and a means for combining the first sound signal and the coded second sound signal into a composite sound signal that can be reproduced by reproducing means in such a manner that the second sound signal is inaudible to the human ear. A transmitter is provided including a first reproducing means, and a receiver having a means for receiving the composite signal, a means for extracting the coded second sound signal from the composite signal, a decoding means, and a second reproducing means.

### RELATED APPLICATION

This application is related to and claims the benefit of priority from French Patent Application No. 05 52824, filed on Sep. 20, 2005, the entirety of which is incorporated herein by reference.

### BACKGROUND OF THE INVENTION

1. Field of the Invention

The present invention relates to a system for reproducing sound and for wirelessly transmitting a sound signal and to the application of that system to a “talking” toy reproducing a sound signal that is transmitted to it wirelessly, inaudibly and invisibly by a television.

2. Description of the Prior Art

Talking toys with objectives close to those of the invention are disclosed in the documents WO 0169572 (Creator Ltd.), DE 19520586 (Siemens AG), US 2004/082255 (P.S.L. Fong et al.), U.S. Pat. No. 6,238,262 (Technovation Australia Pty Ltd.), U.S. Pat. No. 5,191,615 (The Drummer Group), U.S. Pat. No. 4,846,693 (Smith Engineering), U.S. Pat. No. 4,840,602 (Coleco Industries, Inc.).

U.S. Pat. No. 5,191,615, which is closest to the invention, describes a toy (doll) capable of reproducing a sound track that it receives from the outside and performing movements controlled by an external signal. This interactive toy is capable of moving and reproducing sounds synchronized with a soundtrack of a video program, so that the toy appears to be interacting with the video program by responding to it.

The system/toy of U.S. Pat. No. 5,191,615 uses the two sound channels of a stereo system, either in a television transmission signal or in a recording on a recording medium (cassette or DVD). The first sound channel carries the sound of the video program to be reproduced by the television. The second sound channel comprises a sound signal intended to be reproduced by the toy (together with a signal coding kinetic movement instructions intended to be reproduced by the drive systems of the toy).

When the television signal is received by the television or when the recording medium is played back, a splitter isolates the first sound channel, which is reproduced directly by the television. The second sound channel is forwarded to the toy. Demultiplexing, either before forwarding or afterwards (i.e. in the toy), separates the sound intended to be reproduced by the toy by means of a loudspeaker from the signal coding movement instructions.

Transmission between the splitter and the toy is preferably wireless transmission to preserve the full mobility of the toy. U.S. Pat. No. 5,191,615 discloses the use of a frequency modulated (FM) radio link or an infrared link.

In the context of this kind of application, an infrared link proves to be too directional and of too short range to accommodate the movements of a child moving his toy around.

A radio link gives rise to problems of administrative authorization, which may represent a very severe constraint in Europe, for example, and at the very least makes obligatory development work adapted to each country according to the regulations of its frequency allocation authorities.

Another drawback shared by these two transmission modes is that of necessitating adaptation of the television, which must be equipped with a transmitter specifically adapted to infrared or radio transmission.

The present invention removes these drawbacks by proposing a form of transmission that is particularly advantageous in that, when a transmitter/television reproduces a first sound signal, a second sound signal that has been combined with the first sound signal after it has been coded to render it inaudible is reproduced. It can nevertheless be picked up by receiver means in a receiver/toy. The receiver then extracts the second signal and decodes it to render it audible again before reproducing it.

### SUMMARY OF THE INVENTION

The invention consists in a method of producing a composite signal from first and second sound signals, comprising the following steps:

coding the second sound signal to obtain a coded second sound signal that can be reproduced by sound reproducing means in a manner that is inaudible to the human ear, and

combining the first sound signal and the coded second sound signal into a composite sound signal that can be reproduced by sound reproducing means in such a manner that the first sound signal is audible to the human ear and the second sound signal is inaudible to the human ear.

The above kind of composite signal is advantageously compatible with a typical sound signal and may be transmitted, recorded and reproduced by existing means without necessitating modification thereof. When reproduced by standard sound reproducing means, the first sound signal is reproduced audibly but the second sound signal is transmitted in a manner that is inaudible to the human ear. Thus a transmitter comprising standard first reproducing means can reproduce audibly a first sound signal and at the same time transmit a second sound signal inaudibly and wirelessly to a receiver with no additional dedicated means. The receiver can then reproduce said second sound signal audibly by means of second sound reproducing means. This gives the impression that the two sound reproducing means are in dialog.

According to another feature of the invention, the coding step includes shifting the frequency of the second sound signal towards inaudible high frequencies of the reproduction spectrum of the sound reproducing means.

Thus the second signal is rendered inaudible to the human ear whilst remaining within the spectrum that can be reproduced by standard sound reproducing means in order to enable its discreet, wireless transmission without necessitating additional transmission means.

The frequency shift also means that the spectra of the first and second sound signals do not overlap in order to allow them to be combined.

According to the invention, the coding step advantageously includes reducing the bandwidth of the second sound signal.

Said reduction operation prepares for and facilitates the combination operation.

According to the invention, the coding step advantageously includes encryption.

A step of this kind, necessitating decryption, guarantees that said second sound signal can be rendered audibly only by its addressee.

According to the invention, the encryption step advantageously includes eliminating a positive portion of the frequency spectrum of the second sound signal and retaining only the negative portion.

This embodiment has the two-fold advantage that the sound is incomprehensible, even to an ultrasensitive ear, and that the combination step is facilitated by using a more suitable frequency spectrum shape.

According to another feature of the invention, the combination step adds the first sound signal and the coded second sound signal.

A step of this kind has the advantage that it is simple to implement.

According to another feature of the invention, the combination step further includes, prior to the addition, application of a first gain to the first sound signal and application of a second gain to the second sound signal.

According to the invention, the second gain is advantageously lower than the first gain.

This has the advantage of improving the concealment of the masked coded signal (second sound signal) under the universal hearing curve.

According to another advantageous feature of the invention, the combination step includes eliminating a higher portion of the frequency spectrum of the first sound signal before combination and retaining only a lower portion.

This cancellation operation modifies the first sound signal in a manner that is virtually inaudible and greatly facilitates the combination operation by freeing up a portion of the reproduced spectrum.

According to another optional feature of the invention the composite sound signal is transmitted with an identification code identifying at least one destination receiver.

This feature simulates exchanges between a transmitter and a plurality of receivers each having its own sound signal.

According to another optional feature of the invention, a “reproduction” identification code identifies all the receivers.

A “reproduction” identification code advantageously corresponds to all the receivers and allows reproducing to all the receivers.

The invention further relates to a composite signal obtained by any of the above embodiments of the method of the invention.

The protection sought likewise extends to a recording medium for the above kind of composite signal.

The invention further relates to a producer able to produce the above kind of composite signal.

According to another feature of the invention, said producer comprises means for coding the second sound signal that are adapted to execute the coding step and means for combining the first sound signal and the coded second sound signal into a composite sound signal that are adapted to execute the combination step.

According to another feature of the invention, the coding means include first frequency shifting means adapted to shift the frequency of the second sound signal towards inaudible high frequencies of the reproduced spectrum.

According to another feature of the invention, the coding means include means for reducing the bandwidth of the second sound signal.

According to another feature of the invention, the coding means comprise encryption means.

According to another advantageous feature of the invention, the encryption means comprise a low-pass filter retaining only the negative portion of the frequency spectrum of the second sound signal.

According to another feature of the invention, the combination means include an adder for adding the first sound signal and the coded second sound signal.

According to another feature of the invention, the producer of the invention further includes a low-pass filter for eliminating the upper portion of the frequency spectrum of the first sound signal prior to combination.

The invention further relates to a method of reproducing a first sound signal and of transmitting wirelessly a second sound signal, comprising the following steps: producing a composite signal according to the above embodiment from the first and second sound signals, and sound reproducing means reproducing said composite signal.

The invention further relates to a transmitter comprising first sound reproduction means able to reproduce a composite signal conforming to the foregoing embodiment of the invention.

According to another feature of the invention, the transmitter further comprises a producer conforming to any of the above embodiments of the invention.

According to another alternative feature of the invention, the transmitter further comprises means for reading a recording medium.

According to another feature of the invention, the transmitter is integrated into audiovisual means.

According to another feature of the invention, the audiovisual means consist in a television receiver, a sound recorder, a video recorder, a DVD player, a games console, a radio receiver, a personal computer or any other equivalent device capable of reproducing a sound signal.

The invention further relates to a method of receiving a composite sound signal, comprising the following steps: receiving the composite signal according to the above embodiment, extracting the coded second sound signal from the composite signal, decoding the second sound signal in order to reconstruct the second sound signal, and reproducing the second sound signal.

According to another feature of the invention, the decoding step comprises steps in symmetrical corresponding relationship to the steps of the coding step of the production method according to any of the above embodiments.

According to another feature of the invention, the decoding step shifts the frequency of the coded second sound signal towards audible low frequencies, which is the converse of the frequency shifting effected during the coding step.

According to another feature of the invention, the decoding step includes a bandwidth restoration operation that is the converse of the bandwidth reduction operation effected during the coding step.

According to another feature of the invention, the decoding step comprises a decryption operation that is the converse of the encryption operation carried out during the coding step.

According to another feature of the invention, the decrypting step comprises a “mirror” transformation operation for reconstructing the positive portion of the frequency spectrum of the second sound signal from the negative portion of the frequency spectrum of the second sound signal.

According to another feature of the invention, adaptive gain control is applied to the second sound signal before the reproducing step.

The above kind of control means allows reproducing of the second sound signal with a sound volume level independent of the power of the received signal, which may vary as a function of the distance between the transmitter and the receiver.

According to another feature of the invention, a receiver has its own identification code, an identification code for identifying at least one destination receiver is extracted from the composite signal and the receiver reproduces the second sound signal only if its own identification code corresponds to the identification code extracted from the composite signal.

According to another feature of the invention, a “reproduction” identification code corresponds to all the receivers and the extraction of this kind of “reproduction” code is followed by reproduction of the second sound signal.

The invention also relates to a receiver able to receive a composite signal.

According to another feature of the invention, said receiver comprises means for receiving the composite signal, means for extracting the coded second sound signal from the composite signal, means for decoding the coded second sound signal adapted to reconstruct the second sound signal and second sound reproducing means.

According to another feature of the invention, the receiver means consist in a microphone.

Alternatively, according to the invention, the extraction means consist in a band-pass filter or are lumped together with receiver means the bandwidth whereof corresponds to the bandwidth of the signal to be extracted.

According to another feature of the invention, the decoding means comprise symmetrical means in corresponding relationship to the means of the coding means.

According to another feature of the invention, the decoding means include second means for shifting the frequency of the coded second sound signal towards audible low frequencies of the reproduced spectrum, which is the converse of the frequency shift effected by the first frequency shifting means of the coding means.

According to another feature of the invention, the decoding means include means for effecting a bandwidth restoration operation that is the converse of the bandwidth reduction operation effected by the coding means.

According to another feature of the invention, the decoding means comprise means for effecting a decryption operation that is the converse of the encryption operation effected by the encryption means of the coding means.

According to another feature of the invention, the decryption means comprise “mirror” means able to reconstruct the positive portion of the frequency spectrum of the second sound signal from the negative portion of that frequency spectrum.

According to another feature of the invention, the receiver comprises means for adaptive control of the gain of the second sound signal.

According to another feature of the invention, each receiver comprises its own identification code, an identification code identifying at least one destination receiver is extracted from the composite sound signal and a receiver reproduces the second sound signal only if its own identification code corresponds to the extracted identification code.

According to another feature of the invention, a “reproduction” identification code corresponds to all the receivers and the extraction of this kind of “reproduction” code is followed by reproduction of the second sound signal.

According to another feature of the invention, the receiver is integrated into a toy.

According to another feature of the invention, the toy is a doll.

The above features produce “speaking” toys that seem to interact with an audiovisual program reproduced by audiovisual means such as a television, the “voice” of the toy being reproduced by the audiovisual means discreetly and wirelessly.

The invention further relates to a system comprising a producer according to any of the above embodiments producing a composite signal from the first and second sound signals and transferring the composite signal to a transmitter or primary sound reproducer according to any of the above embodiments for reproducing the first sound signal and wirelessly transmitting the second sound signal to at least one receiver or secondary sound reproducer according to any of the above embodiments for extracting and decoding the second sound signal in order to reproduce it.

Other features, details and advantages of the invention will emerge more clearly from the detailed description given hereinafter by way of illustration and with reference to the appended drawings.

### BRIEF DESCRIPTION OF THE DRAWINGS

FIG. 1 is a general block diagram of the system of the invention.

FIG. 2 is a block diagram of a producer of the invention.

FIG. 3 is a block diagram of a transmitter of the invention.

FIG. 4 is a block diagram of a receiver of the invention.

FIG. 5 shows the frequency spectrum of a first sound signal.

FIG. 6 shows the frequency spectrum of a first sound signal and the elimination of an upper portion of that spectrum.

FIG. 7 shows the frequency spectrum of a first sound signal after eliminating its upper portion.

FIG. 8 shows the frequency spectrum of a second sound signal.

FIG. 9 shows the frequency spectrum of a second sound signal whose spectrum has been reduced.

FIG. 10 shows the complete frequency spectrum of a second signal (positive portion and negative portion).

FIG. 11 shows the frequency spectrum of the negative portion of a second sound signal.

FIG. 12 shows the frequency spectrum of a second signal shifted into the high frequencies.

FIG. 13 shows the frequency spectrum of a first sound signal combined with a second sound signal to produce a composite signal.

FIG. 14 shows the operation of extracting the second sound signal from the composite signal.

### DETAILED DESCRIPTION OF THE PREFERRED EMBODIMENTS

In the various figures, the same reference numbers designate identical or similar items. A reference comprising a letter and a number is used to designate different forms of the same object. For example, the references 5a-5e designate the same second sound signal 5 in the various forms (reduced, encrypted, coded, etc.) that it assumes in the course of the transformations applied to it by the various processes of the invention.

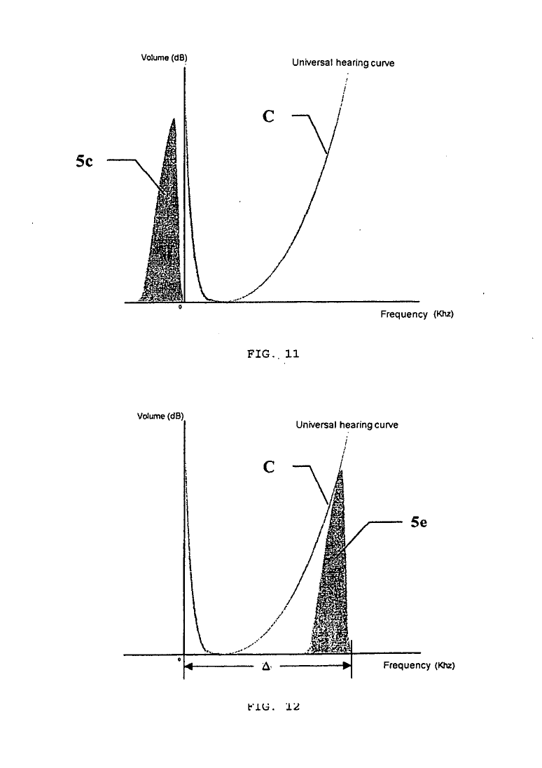

FIGS. 5 to 12 show sound signals. A common representation is employed using a frequency spectrum diagram in which the abscissa axis represents frequencies expressed in Hz or kHz and the ordinate axis represents sound volumes expressed in dB.

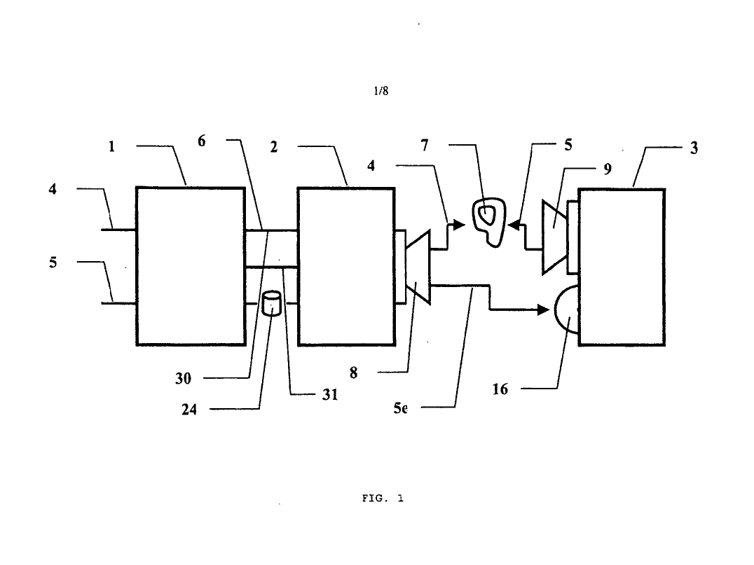

FIG. 1 shows one embodiment of a system of the invention. The system includes a producer 1, a transmitter 2 and at least one receiver 3.

The producer 1 receives a first sound signal 4 and a second sound signal 5. The first sound signal 4 is at this stage in a basic form 4a shown in FIG. 5. The second sound signal 5 is at this stage in a basic form 5a shown in FIG. 8 and substantially identical to that 4a of the first sound signal 4. The producer 1 is a signal processor unit producing a composite signal 6 from a first sound signal 4 and a second sound signal 5 by a method described in detail later.

The composite signal 6 is transferred to the transmitter 2 via a direct connection 30, a reproduction connection 31, a recording medium 24 or any equivalent means known to the person skilled in the art.

The transmitter 2, also called the primary sound reproducer, reproduces the composite signal 6 by means of first sound reproducing means 8. The effect of this is sound reproducing of the first sound signal 4 in a form that is audible to the human ear 7 and reproducing of the second sound signal 5 in its coded form 5e in a manner that is inaudible to the human ear 7.

One or more receivers 3, also called secondary sound reproducers, situated within the sound reproducing range of the transmitter 2 receive the portion of the composite signal 6 comprising the coded second sound signal 5e. The receiver 3 extracts the coded second sound signal 5e and decodes it to reconstruct the basic form 5a of the second sound signal 5. Then, by means of second sound reproducing means 9, the receiver 3, also called the secondary sound reproducer, reproduces the second sound signal 5 in a form that is audible to the human ear 7.

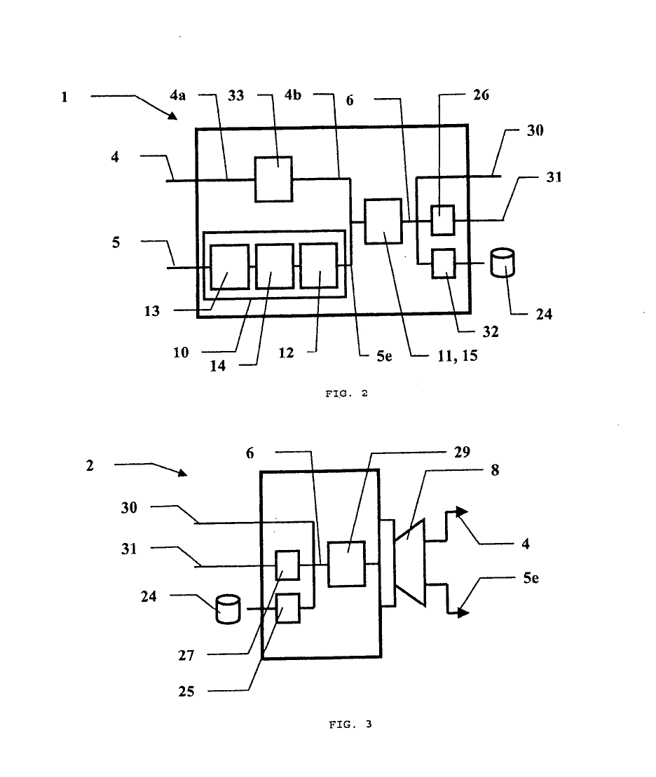

FIG. 2 shows in detail one embodiment of the producer 1, which comprises coding means 10 for coding the second sound signal 5 to transform it into a coded second signal 5e. It further comprises combination means 11 for combining, or multiplexing, the first sound signal 4 and the coded second sound signal 5e to produce a composite signal 6.

In order to render the second signal 5 inaudible during reproducing of the composite signal 6, the coding means 10 advantageously comprise first frequency shifting means 12 for shifting the frequency spectrum of the second signal 5 towards high frequencies above the frequencies audible to the human ear 7.

FIG. 12 shows a signal 5e of this kind shifted by an amount Delta towards the high frequencies of the frequency spectrum. This same FIG. 12 shows a curve C representing the lower limit of the frequency spectrum generally audible by the human ear 7, known as the universal hearing curve c. However, the frequency shift Delta is such that the coded second sound signal 5e obtained in this way remains within a reproduction frequency spectrum such that it can be reproduced by conventional sound reproducing means 8. The frequency shifting means 12 constitute essential means of the coding means 10.

The frequency shifting means 12 take the form of a frequency multiplier, for example.

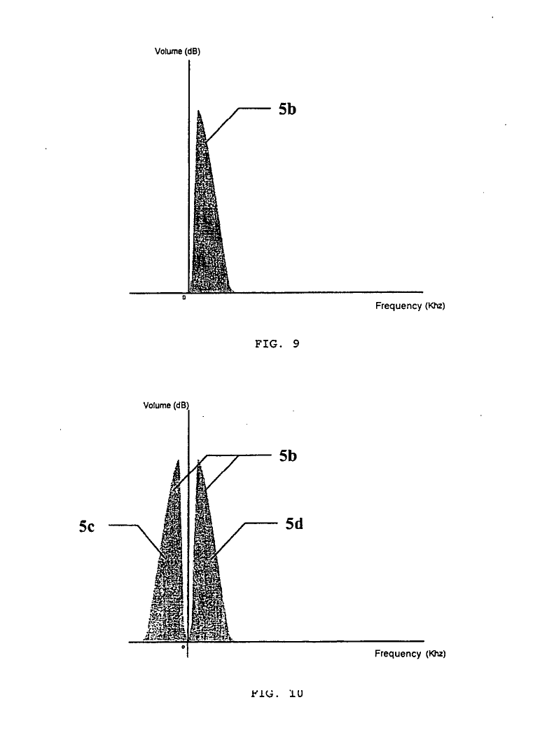

To limit use of the reproduction frequency spectrum, the coding means 10 advantageously further include means 13 for reducing the bandwidth of the second sound signal 5. The means 13 or method of reducing the bandwidth are known to the person skilled in the art and need not be described in detail here. The aim of this kind of frequency spectrum reducing method or means is to reduce the range of the frequency spectrum used by the signal, either by compressing the frequency spectrum or by selectively and deliberately eliminating a portion of the spectrum in order to retain only a restricted band. The residual portion nevertheless remains sufficient to allow restoration. For example, if a band only approximately 3 kHz wide is retained, containing the frequencies used most often, it is possible to restore the initial sound signal. A very high pitched xylophone piece could not be restored, however, as its frequencies are not retained during reduction. This kind of reduction process typically converts the basic signal 5a shown in FIG. 8 into the reduced spectrum signal 5b shown in FIG. 9.

The coding means 10 may advantageously comprise encryption means 14 that modify the content of the second sound signal 5 in order to render it incomprehensible. This guarantees that only an authorized receiver will be able to decrypt the signal to copy it or reproduce it, for example.

FIG. 10 shows a signal 5b with its complete frequency spectrum, comprising a negative portion 5c and a positive portion 5d. The negative portion of the frequency spectrum is always present in a signal. The negative portion 5c is symmetrical to the positive portion 5d with respect to the ordinate axis. As it does not contribute any additional information, this negative portion 5c is generally omitted from frequency representations. One example of an encryption method used by encryption means 14 eliminates the positive portion 5d of the frequency spectrum of the second sound signal 5 and retains only the negative portion 5c. This kind of encryption may be effected by encryption means 14 comprising a low-pass filter retaining only the negative portion 5c of the frequency spectrum. This kind of encryption may further be effected by applying a “mirror” symmetry process to only the positive portion 5d of the spectrum.

Encryption of this kind has a two-fold objective. The first objective is encryption as such. Assuming that it could be perceived, for example by a person with ultrasensitive hearing, the encrypted signal obtained in this way would be no less unintelligible. The second objective, given the new spectrum shape obtained, is to facilitate the combination step. As shown in FIG. 12, the new shape of the spectrum of the negative portion signal 5c, after it has been frequency shifted to a yield a signal 5e, is easier to conceal under the universal hearing curve C or necessitates a smaller shift Delta.

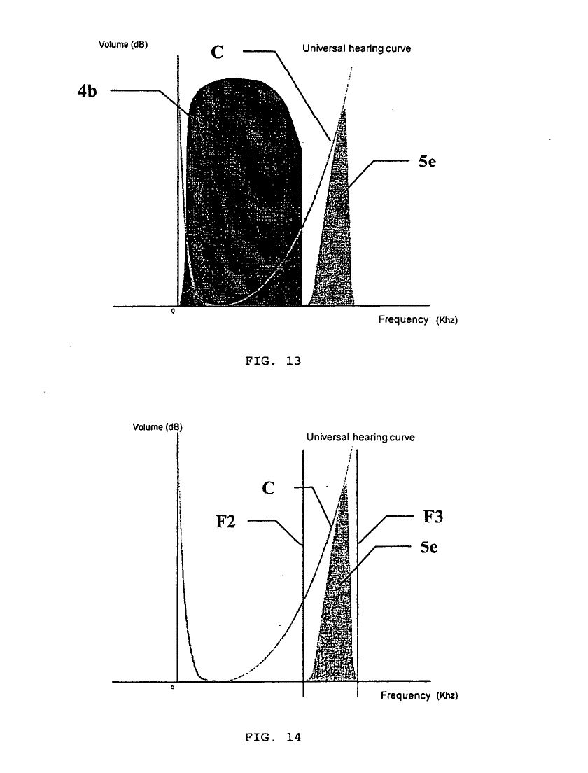

The combination means 11 construct the composite signal 6 from the first sound signal 4, where appropriate converted to a suitable form, and the second sound signal 5, also converted to a suitable form, for example the coded form 5e. As shown in FIG. 13, forming the two sound signals 4, 5 in this way has the objective of producing frequency spectra of the two sound signals that do not overlap but that both remain in a reproduction spectrum that can be reproduced by reproducing means 8. Thus combination, which here consists of frequency-division multiplexing, may be effected by combination means 11 that comprise an adder 15 that adds the first sound signal 4 and the second sound signal 5, preferably in its coded form 5e.

Before adding them, it is advantageous to apply a first gain to the first sound signal 4 and a second gain to the second sound signal 5 to compensate any attenuation of either of the sound signals, either a priori or a posteriori.

The second gain is advantageously lower than the first gain so that the coded second sound signal 5e is even more concealed under the universal hearing curve C.

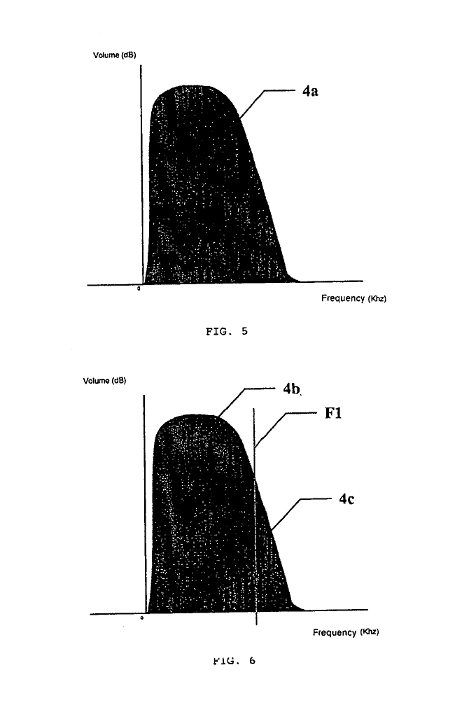

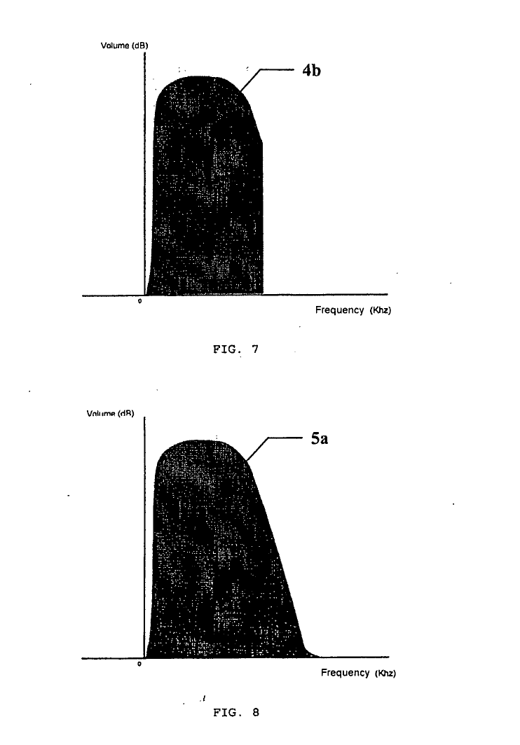

Prior to the combination operation, it is advantageous to modify the spectrum of the signal 4 to eliminate an upper portion thereof. FIGS. 6 and 7 show this kind of modification. The operation consists in eliminating an upper portion 4c of the frequency spectrum of the first sound signal 4 and retaining only a lower portion 4b. A frequency F1 is selected that determines the upper limit of the spectrum and separates the lower portion 4b from the upper portion 4c. A low-pass filter 33 of characteristic frequency F1 can advantageously perform this operation. The low-pass filter 33 may be integrated into the combination means 11 or, as shown in FIG. 2, constitute a separate unit on the input side of the combination means 11. As shown in FIG. 7, it is the lower portion signal 4b that is advantageously combined with the coded form 5e of the second sound signal 5.

As shown in FIG. 13, the spectrum portion freed up by eliminating said upper portion 4c is exploited to position the coded form 5e of the second sound signal 5 without the two signals overlapping and without them occupying too much of the bandwidth of the reproducing spectrum that can be reproduced by standard reproducing means. The frequency F1 is selected so that the coded second sound signal 5e may be placed inside said reproducing spectrum. If the second sound signal is reduced beforehand, the upper portion 4c removed from the basic signal 4a advantageously remains narrow. What is more, this region of the frequency spectrum, corresponding to high frequencies, is not of great importance in terms of the sound quality perceived by the human ear 7. Because of this, eliminating said higher portion 4c to retain only the lower portion of the signal 4b modifies the first sound signal 4 as perceived by the human ear 7 only slightly, but greatly facilitates combining the second sound signal 5 with the first sound signal 4.

In one particular embodiment, it is possible to add to the composite signal 6 an identification code identifying at least one intended receiver 3. In an embodiment of this kind, the system comprises at least one producer 1, at least one transmitter 2 and a plurality of receivers 3. Each receiver 3 of said plurality of receivers is identified by its own identification code. The identification codes may be different for each receiver 3 or common to a plurality of receivers 3 of a “family” intended to reproduce the same second sound signals 5. During production by the producer 1 and transmission by the transmitter 2 of a second sound signal 5, the latter signal is accompanied, in the composite signal 6, by an identification code corresponding to the receivers that have to reproduce the second sound signal 5. The receivers 3 whose identification codes do not correspond to the identification code transmitted receive the second sound signal 5 but do not reproduce it.

Another optional embodiment uses a “reproduction” identification code that is not assigned to any receiver 3 in particular but is only inserted into the composite signal 6 and recognized by any receiver 3 as an identification code corresponding to that receiver 3, regardless of its own identification code, authorizing said receiver 3 to reproduce the second sound signal 5 that the “reproduction” code accompanies. The person skilled in the art will not fail to generalize the present teaching employing identification codes to selecting a subset of the plurality of receivers 3, for example using addressing or masking techniques.

Identification codes may be inserted into the composite signal 6 by any means known to the person skilled in the art. The present invention is not concerned with such insertion, which is not described in detail here.

Still referring to FIG. 2, the composite signal 6 produced by the producer 1 as described above is then forwarded to a transmitter 2. At the output of the combination means 11, the producer 1 has a choice of a direct connection 30, a transmitter 26 on a reproduction link 31 or, if said composite signal is not intended to be used afterwards, means 32 for writing a recording medium 24. The reproduction link 31 may be of any cable or wireless analog or digital type known to the person skilled in the art. Examples include FM reproducing of a radio or television program and a serial, USB or ADSL data link. For example, the recording medium 24 may be an audiocassette, a videocassette (VHS, etc.), a DVD, a CD, a CD-ROM or any other equivalent medium known to the person skilled in the art able to record an analog or digital sound signal. One form of the composite signal 6 is transferred to the transmitter 2.

FIG. 3 shows this kind of transmitter 2 in detail. Corresponding means able to receive said composite signal 6 produced by the producer 1 are provided at the input of the transmitter 2, in the form of a direct line 30, a receiver 27 compatible with the transmitter 26 using the reproduction link 31 or reading means 25 able to read a recording medium 24.

In an alternative embodiment, the producer 1 is integrated into the transmitter 2.

The transmitter 2 has a primary reproducer function and thus the function of reproducing the first sound signal 4. For this purpose it essentially comprises first sound reproducing means 8 that typically comprise at least one loudspeaker or any other similar device. It advantageously further comprises processing means 29 comprising the elements necessary for shaping a sound signal before it is reproduced. Here the processing means 29 include the necessary means for reading the medium 24 and producing a signal in a form that can be reproduced by said first sound reproducing means 8. These means are well known to the person skilled in the art, form part of the prior art and do not part of the invention.

Note that these components are standard components that do not have to be modified to implement the invention. The composite signal 6 has all the attributes of a standard sound signal 4a (FIG. 5) or 5a (FIG. 8). It can therefore be reproduced by standard first sound reproducing means 8. Thus the transmitter 2 does not have to be modified in accordance with the invention. Any existing reproducing equipment may be used to implement the invention. Thus a cassette player, a television and any audio or video reproducing system are suitable. It suffices to replace the input sound signal with the composite signal 6 at the input of this kind of audiovisual means. Thus a standard television can reproduce the composite signal 6 substituted for the sound signal received from a television broadcast or cable network. Similarly, a DVD player can reproduce a composite signal 6 recorded on a DVD instead of a soundtrack.

During reproducing of the composite signal 6 as shown in FIG. 13 by the first sound reproducing means 8 of the transmitter 2, all components of the composite signal 6 are reproduced, i.e. those originating from the first sound signal 4, 4b and those originating from the second sound signal 5, 5e. However, given the universal hearing curve C represented in the same FIG. 13, only the portion above said curve C is audible and perceptible by the human ear 7. The greater portion of the first sound signal 4 in its form 4b is above this curve C and is therefore audible to the human ear 7. Moreover, this portion above the curve C is substantially identical to the portion of the first sound signal 4 on its own in its basic form 4a above the curve C (FIG. 5). As a result the human ear 7 hears substantially the same sound as if the first reproducing means 8 were to reproduce the first sound signal 4 on its own in its basic form 4a. To the human ear 7 it is exactly as if the transmitter 2 had reproduced the first sound signal 4. For this reason, the transmitter 2 is also called the primary sound reproducer.

The second sound signal 5 in its coded form 5e is situated entirely below the universal hearing curve C and is not normally perceived by the human ear 7, to which it remains inaudible.

It should nevertheless be pointed out that the portion of the composite signal 6 derived from the second sound signal 5 and coded in the form of an inaudible signal 5e is in fact reproduced.

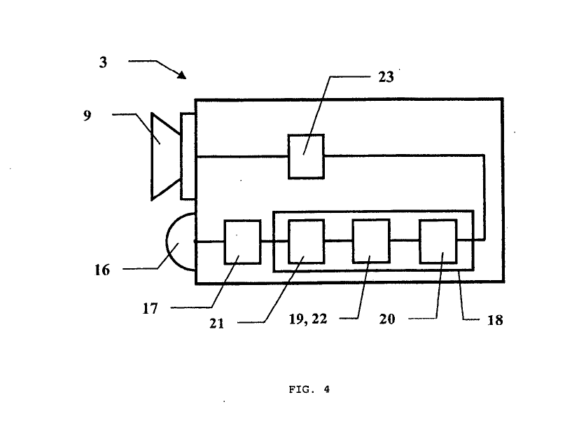

FIG. 4 shows in detail one embodiment of a receiver 3 or secondary sound reproducer of the invention. A receiver 3 of this kind is able to receive a composite signal 6 and extract the second sound signal 5 from it, where applicable in its coded form 5e. To this end the receiver 3 comprises means 16 for receiving the composite signal 6 and means 17 for extracting the second sound signal 5, 5e combined into said composite signal 6. To this end the receiving means 16 have a usable bandwidth covering at least the portion of the frequency spectrum of the composite signal containing the second sound signal 5, 5e. Note that it is not necessary for the receiving means 16 to pick up the portion of the spectrum corresponding to the first sound signal 4. On the other hand, it is an essential feature of the invention that, unlike the human ear 7, the receiving means 16 be capable of picking up the portion of the spectrum of the composite signal 6 derived from the second sound signal 5, 5e.

A first embodiment of the receiving means 16 receives a portion of the spectrum of the composite signal 6 including the portion derived from the second sound signal 5, 5e. Extraction means 17 then separate only the useful portion of the received signal. In this case the extraction means typically consist of a band-pass filter. FIG. 14 shows the extraction step. The coded form 5e of the second sound signal 5 is extracted from the received spectrum by retaining only a portion of the frequency spectrum between two frequencies F2 and F3. In an alternative second embodiment, the extraction means 17 are lumped together with the receiving means 16 in that said receiving means 16 have a bandwidth corresponding to the portion of the spectrum between the two frequencies F2 and F3.

The receiving means 16 typically consist of a microphone.

The receiver 3 further comprises decoding means 18 able to decode the coded second sound signal 5e in order to reconstruct the second sound signal 5 in its basic form 5a.

The receiver 3 further comprises second sound reproducing means 9 which reproduce the second sound signal 5a audibly.

The person skilled in the art will readily deduce from the present description that the various forms of processing applied to the second sound signal 5 (coding, encryption, reduction, transmission, reception, etc.) may be carried out in the analog or digital domain. It will likewise be apparent to him that, regardless of the technology adopted, the processing times are very short and induce only negligible delays. The transmission and subsequent reproducing of the second sound signal from the transmitter 2 to the receiver 3 for reproducing by the second sound reproducing means 9 are effected in real time and substantially simultaneously.

The person skilled in the art will further note that the frequency separation of the first sound signal 4 and the second sound signal 5 in the composite signal 6 authorizes simultaneous use of the two sound signals 4, 5. The receiver/toy can therefore “speak” or “sing” at will at the same time as the transmitter/television is reproducing its own sound signal, without any “half duplex” procedure and without any protocol in respect of who is to speak next.

The decoding means 18 may take various forms and preferably comprise symmetrical means in corresponding relationship to the means of the coding means 10 in order to carry out decoding operations that are the converse of the coding operations carried out during coding by the coding means 10 and in the reverse order.

The frequency shifting step being essential during coding, the decoding means 18 necessarily include second means 21 for shifting the frequency of the coded second sound signal 5e. As the first frequency shifting means 12 effect a frequency shift of height Delta towards the high frequencies, the second frequency shifting means 21 effect a frequency shift of exactly the same height Delta towards the low frequencies. This reconstructs an audible sound signal. In the same way that the first frequency shifting means 12 may advantageously take the form of a frequency multiplier, the second frequency shifting means 21 may advantageously take the form of a frequency divider.

The other components of the decoding means 18 and the associated steps are optional and are present only to the degree that corresponding means are symmetrically present in the coding means 10.

Thus if the coding means 10 include bandwidth reduction means 13, the decoding means 18 include bandwidth restoration means 20 that are the converse of said bandwidth reduction means 13.

Again, if the coding means 10 include encryption means 14, the decoding means 18 comprise decryption means 19 that are the converse of said encryption means 14.

Accordingly, if the encryption means 14 of the coding means 10 eliminate the positive portion 5d of the spectrum of the second sound signal 5 and retain only the negative portion 5c, the decryption means 19 comprise means 22 for reconstructing the complete signal 5b comprising both the positive portion 5d and the negative portion 5c. Such means 22 consist of “mirror” means, for example, for reconstructing the positive portion 5d from the negative portion 5c by considerations of symmetry with respect to the ordinate axis.

The person skilled in the art will note that the order of the various coding/decoding means (reduction 13/restoration 20, frequency shifting 12/21 and encryption 14/decryption 19, 22) and the various associated coding/decoding steps may be modified. Thus spectrum reduction and/or encryption may precede or follow frequency shifting. The person skilled in the art will know how to select the order of these operations as a function of the means available and whether they operate at low frequencies or at high frequencies. Note, however that in all cases the order of the decoding means/operations is preferably the opposite of the order of the coding means/operations.

In one advantageous embodiment, shown in FIG. 4, the receiver comprises adaptive gain control means 23 that apply to the second sound signal 5 coming from the decoding means 18 an adaptive gain control process known in the art so that the sound volume of the second sound signal 5 as reproduced by the second sound reproducing means 9 is independent of the amplitude of the signal received by the receiver means 16. It is thus possible to reproduce the second sound signal 5 with a constant volume despite variations of said amplitude caused by variations of the distance between the transmitter 2 and the receiver 3.

As stated above, the composite signal 6 may include an identification code of the intended receiver(s) 3. The receiver 3 is then advantageously assigned its own identification code and includes means for extracting the identification code included in and transmitted with the composite signal 6. The receiver 3 compares the identification code transmitted to its own identification code and reproduces the second sound signal 5 only if the two identification codes match.

A particular “reproduction” identification code is recognized by all the receivers 3 as corresponding to said receiver 3. In the event of reception of a signal accompanied by a “reproduction” code, the second sound signal 5 is reproduced by the receiver 3 regardless of its own identification code.

One particular embodiment of a receiver 3 is integrated into a toy. That toy may be a doll, for example.

There is claimed:

1. A method of producing a composite signal from first and second sound signals, comprising the following steps:
coding said second sound signal to obtain a coded second sound signal that can be reproduced by sound reproducing means in a manner that is inaudible to the human ear, and
combining said first sound signal and said coded second sound signal into a composite sound signal that can be reproduced by sound reproducing means in such a manner that said first sound signal is audible to the human ear and said second sound signal is inaudible to the human ear.

2. A production method according to claim 1 wherein said coding step includes shifting the frequency of said second sound signal towards inaudible high frequencies of the reproducing spectrum of said sound reproducing means.

3. A production method according to claim 2 wherein said coding step includes reducing the bandwidth of said second sound signal.

4. A production method according to claim 3 wherein said coding step includes encryption.

5. A production method according to claim 4 wherein said encryption step includes eliminating a positive portion of the frequency spectrum of said second sound signal and retaining only the negative portion.

6. A production method according to claim 5 wherein said combination step adds said first sound signal and said coded second sound signal.

7. A production method according to claim 6 wherein said combination step further includes, prior to said addition, application of a first gain to said first sound signal and application of a second gain to said second sound signal.

8. A production method according to claim 7 wherein said second gain is lower than said first gain.

9. A production method according to claim 8 including a step of eliminating a higher portion of the frequency spectrum of said first sound signal before combination and retaining only a lower portion.

10. A composite signal obtained by the method according to any one of claim 1.

11. A recording medium for recording a composite signal according to claim 10.

12. A producer adapted to produce a composite signal according to claim 10.

13. A method of reproducing a first sound signal and of transmitting wirelessly a second sound signal, comprising the following steps:
producing a composite signal according to claim 12 from said first and second sound signals, and
reproducing said composite signal via a sound reproducing means.

14. A method of receiving a composite sound signal according to claim 10, comprising the following steps:
receiving said composite signal,
extracting said coded second sound signal from said composite signal,
decoding said second sound signal in order to reconstruct said second sound signal, and
reproducing said second sound signal.

15. A reception method according to claim 14 wherein the decoding step comprises steps in symmetrical corresponding relationship to the steps of the coding step.

16. A receiver adapted to receive a composite signal according to claim 10.

17. A system for reproducing first and second sound signals, comprising:
a producer according to claim 12 producing a composite signal from said first and second sound signals and transferring said composite signal to:
a transmitter or primary sound reproducer for reproducing said first sound signal and wirelessly transmitting said second sound signal to:
at least one receiver or secondary sound reproducer adapted to receive a composite signal, for extracting and decoding said second sound signal in order to reproduce it.
